(19) United States
(12) Patent Application Publication
(10) Pub. No.: US 2005/0054210 A1
(43) Pub. Date: Mar. 10, 2005

(54) Multiple exposure method for forming patterned photoresist layer

(75) Inventors: Shin-Rung Lu, Hsin-Chu (TW); Kun-Hong Lin, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/656,986

(22) Filed: Sep. 4, 2003

(51) Int. Cl. G03C 5/04; H01L 21/302; H01L 21/461

(52) U.S. Cl. 438/725; 430/494

(57) ABSTRACT

A method for exposing a blanket photoresist layer employs exposing a minimum of two non-overlapping die sub-patterns within a single die region of the blanket photoresist layer, each exposed while employing a minimum of two separate masks. The use of the multiple masks and multiple sub-patterns provides upon development a patterned photoresist layer with enhanced dimensional precision and uniformity.

### BACKGROUND OF THE INVENTION

1. Field of the Invention

The invention relates generally to photolithographic methods employed in forming microelectronic products. More particularly, the invention relates to methods for forming patterned photoresist layers employed in forming microelectronic products.

2. Description of the Related Art

Microelectronic products are formed from substrates over which are formed microelectronic devices that are connected and interconnected with patterned conductor layers. The patterned conductor layers are separated by dielectric layers.

Microelectronic devices and patterned layers are formed within microelectronic products while employing photolithographic methods. The photolithographic methods provide patterned photoresist layers that are employed as mask layers when etching, depositing, implanting or otherwise processing or fabricating microelectronic structures within microelectronic products.

While patterned photoresist layers are generally essential when fabricating microelectronic products, they are nonetheless not entirely without problems. In that regard, it is often difficult to fabricate patterned photoresist layers with adequate dimensional precision across die patterns within microelectronic products.

It is thus desirable to fabricate patterned photoresist layers with enhanced dimensional precision. The invention is directed towards the foregoing object.

### SUMMARY OF THE INVENTION

A first object of the invention is to provide a method for forming a patterned photoresist layer within a microelectronic product.

A second object of the invention is to provide a method in accord with the first object of the invention, wherein the patterned photoresist layer is formed with enhanced dimensional precision.

In accord with the objects of the invention, the invention provides a method for exposing a photoresist layer.

The method first provides a substrate having formed thereover a photoresist layer. The method also provides for separately exposing a minimum of two non-overlapping sub-patterns within a single die region within the photoresist layer while employing a minimum of two masks, to form an exposed photoresist layer.

Within the invention, each of the minimum of two non-overlapping sub-patterns may be exposed employing separate exposure conditions, such as to effect optimal properties within a patterned photoresist layer formed from the exposed photoresist layer.

The invention provides a method for forming a patterned photoresist layer with enhanced dimensional precision within a microelectronic product.

The invention realizes the foregoing object by exposing a minimum of two non-overlapping sub-patterns within a single die region within a photoresist layer formed over a substrate when forming therefrom an exposed photoresist layer. Due to the use of the minimum of two non-overlapping sub-paterns, an exposed blanket photoresist layer may be formed with differing exposure conditions in different sub-pattern regions and thus a patterned photoresist layer formed from the exposed photoresist layer may be formed with enhanced dimensional precision.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 shows a schematic perspective view diagram of a microelectronic product that may be fabricated in accord with the preferred embodiment of the invention.

FIG. 2 shows a schematic perspective view diagram of a photomask that may be employed in accord with the preferred embodiment of the invention.

FIG. 3 shows a schematic plan view diagram of a die pattern that is desired to be exposed in accord with the invention.

FIG. 4A, FIG. 4B, FIG. 4C and FIG. 4D show a series of masks defining a series of sub-patterns that may be employed for forming the die pattern of FIG. 3.

FIG. 5 shows a series of schematic plan view diagrams illustrating the results of progressive stages of fabricating the die pattern of FIG. 3 while employing the series of masks of FIG. 4A to FIG. 4D.

### DESCRIPTION OF THE PREFERRED EMBODIMENT

The invention provides a method for forming a patterned photoresist layer with enhanced dimensional precision within a microelectronic product.

The invention realizes the foregoing object by exposing a minimum of two non-overlapping sub-patterns within a single die region within a photoresist layer formed over a substrate when forming an exposed photoresist layer. Due to the use of the minimum of two non-overlapping sub-patterns, the exposed photoresist layer may be formed with differing photoexposure conditions in different sub-pattern regions and thus a patterned photoresist layer formed from the exposed photoresist layer may be formed with enhanced dimensional precision.

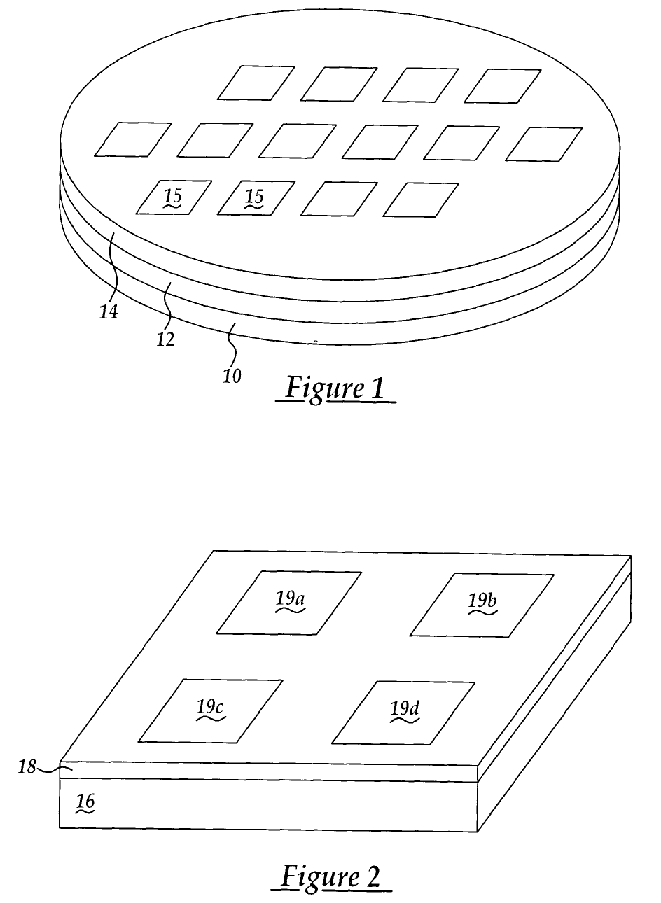

FIG. 1 shows a schematic perspective view diagram of a microelectronic product that may be fabricated in accord with the invention.

The microelectronic product comprises a substrate 10 having formed thereover a blanket target layer 12 in turn having formed thereupon a blanket photoresist layer 14.

The substrate 10 may be employed within a microelectronic product selected from the group including but not limited to semiconductor products, ceramic substrate products and optoelectronic products. The blanket target layer 12 may be formed of materials selected from the group including but not limited to conductor materials, semiconductor materials and dielectric materials. The blanket photoresist layer 14 may be formed of either positive photoresist materials or negative photoresist materials.

Preferably: (1) the substrate 10 is a semiconductor substrate having formed thereupon a gate dielectric layer; (2) the blanket target layer 12 is a blanket gate electrode material layer formed to a thickness of from about 1500 to about 3500 angstroms; and (3) the blanket photoresist layer 14 is formed of a positive photoresist material formed to a thickness of from about 10000 to about 20000 angstroms.

FIG. 1 also shows a series of die regions 15 within the blanket photoresist layer 14. The series of die regions 15 is otherwise conventional in the microelectronic fabrication art, and in particular within the semiconductor product fabrication art. Typically, each die region 15 within the series of die regions 15 encompasses projected areal dimensions of from about 5 to about 20 millimeters. Within the invention, it is intended that a die pattern be exposed into the blanket photoresist layer within each of the die regions 15 to form an exposed blanket photoresist layer. Upon development thereof to form a patterned photoresist layer, the patterned photoresist layer may be employed for further processing of the blanket target layer 12. The further processing of the blanket target layer 12 may include etching thereof to form a patterned target layer, as is otherwise conventional in the microelectronic product fabrication art.

FIG. 2 shows a photomask that may be employed in part to fabricate the microelectronic product of FIG. 1 in accord with the invention.

FIG. 2 shows a transparent substrate 16 having formed thereupon a blanket opaque material layer 18. The blanket opaque material layer 18 has defined therein a series of mask pattern regions 19a, 19b, 19c and 19d, the specific patterns of which are not illustrated in FIG. 2. Each of the mask pattern regions 19a, 19b, 19c and 19d is intended to be of appropriate sizing such as to expose one of the die regions 15 within the blanket photoresist layer 14 of FIG. 1 to form therein a die pattern.

The transparent substrate 16 may be formed of a transparent material such as but not limited to quartz or glass. Typically, the transparent substrate is formed to a thickness of from about 1 to about 10 millimeters.

The patterned opaque material layer 18 may be formed of opaque materials such as but not limited to metals and metal alloys. Typically, the patterned opaque material layer 18 is formed of a chromium opaque material formed to a thickness of from about 200 to about 500 angstroms.

Typically, each of the mask pattern regions 19a, 19b, 19c and 19d has contained therein a pattern as is discussed in further detail below.

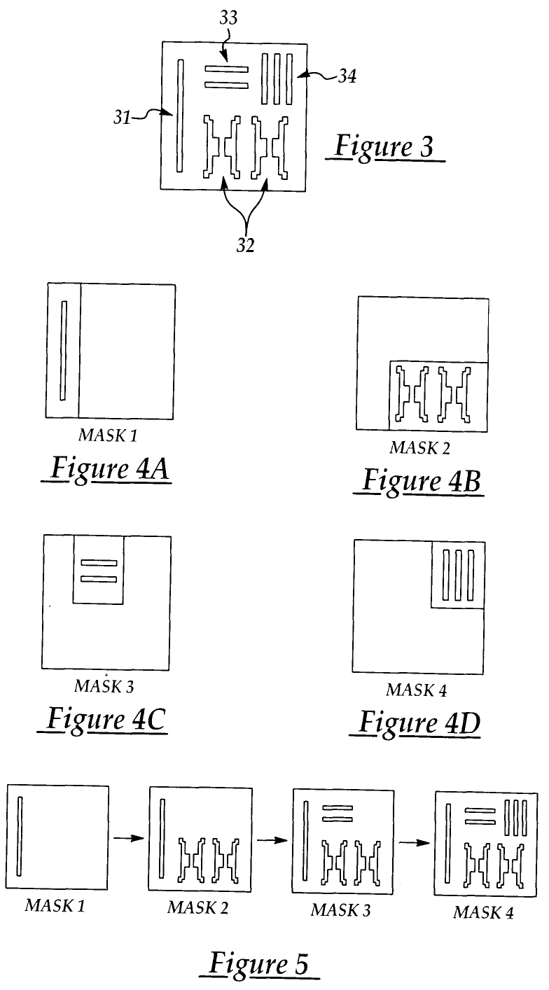

FIG. 3 illustrates a die pattern that may be formed into a die region within a blanket photoresist layer in accord with the preferred embodiment of the invention. The die pattern comprises four die sub-patterns including: (1) an isolated die sub-pattern 31; (2) an intricate die sub-pattern 32; (3) a horizontal die sub-pattern 33; and (4) a vertical die sub-pattern 34.

When photoexposing a blanket photoresist layer to form a patterned photoresist layer having formed therein the die pattern as illustrated in FIG. 3, it is often difficult to provide a photoexposed die pattern that in turn develops into a patterned photoresist layer with enhanced dimensional precision. The difficulties often derive from differences in pattern density, as well as pattern complexity. The invention is intended to provide a method for compensating for the foregoing differences, such as to provide a patterned photoresist layer with enhanced dimensional precision.

FIG. 4A to FIG. 4D show a series of schematic plan view diagrams illustrating a series of four separate photomasks, one directed towards each of the four sub-patterns of the die pattern of FIG. 3. Within FIG. 4a to FIG. 4d, each of the photomasks is intended to expose only one each of the separate die sub-patterns 31, 32, 33 and 34 as illustrated in FIG. 3. Upon photoexposure with the series of masks as illustrated in FIG. 4A to FIG. 4D, each of the series of die sub-patterns is exposed and is non-overlapping. FIG. 4A shows a schematic plan view diagram of a photomask intended to expose an isolated sub-pattern. FIG. 4B shows a photomask intended to expose an intricate sub-pattern. FIG. 4C shows a photomask intended to expose a horizontal sub-pattern. FIG. 4D shows a photomask intended to expose a vertical sub-pattern. The series of photomasks as illustrated in FIG. 4A to FIG. 4D may be fabricated into a single integrated photomask as illustrated in FIG. 2, or may be provided as separate photomasks.

FIG. 5 shows a series of schematic plan-view diagrams illustrating the results of progressive stages of exposing a die pattern into an exposed photoresist layer with the series of photomasks as illustrated in FIG. 4A to FIG. 4D, to provide a die pattern as illustrated in FIG. 3.

Within FIG. 5, the exposures are undertaken sequentially employing the isolated sub-pattern mask as illustrated in FIG. 4A, the intricate sub-pattern mask as illustrated in FIG. 4B, the horizontal sub-pattern mask as illustrated in FIG. 4C and the vertical sub-pattern mask as illustrated in FIG. 4D.

Within the invention, in conjunction with employing each of the separate masks to provide the sequential accumulated photoexposures as illustrated in FIG. 5, photoexposure conditions employed within a sequential series of four photoexposures employed within FIG. 5 may also be changed. Such changes may be effected such as to provide precise linewidth dimensions when forming a patterned photoresist layer from an exposed photoresist layer. The photoexposure conditions may include, but are not limited to: (1) photoexposure energy; (2) depth of focus; and (3) photoexposure illumination.

While the preferred embodiment of the invention illustrates the invention within the context of a die pattern formed employing four accumulated photoexposures and photomasks (either separate or integrated), the present invention also contemplates a die pattern formed employing at least two accumulated photoexposures and photomasks.

As is understood by a person skilled in the art, the preferred embodiment of the invention is illustrative of the invention rather than limiting of the invention. Revisions and modifications may be made to methods, materials, structures and dimensions in accord with the preferred embodiment of the invention while still providing an embodiment in accord with the invention, further in accord with the appended claims.

1. A method for exposing a blanket photoresist layer comprising:
providing a substrate having formed thereover a photoresist layer; and
exposing within a single die region within the photoresist layer a minimum of two non-overlapping die sub-patterns while employing a minimum of two masks.

2. The method of claim 1 wherein the substrate is a semiconductor substrate.

3. The method of claim 1 wherein the substrate is a ceramic substrate.

4. The method of claim 1 wherein the blanket photoresist layer is formed of a positive photoresist material.

5. The method of claim 1 wherein the blanket photoresist layer is formed of a negative photoresist material.

6. A method for exposing a photoresist layer comprising:
providing a substrate having formed thereover a photoresist layer; and
exposing within a single die region within the photoresist layer a minimum of two non-overlapping die sub-patterns while employing a minimum of two masks and two exposure conditions.

7. The method of claim 6 wherein the substrate is a semiconductor substrate.

8. The method of claim 6 wherein the substrate is a ceramic substrate.

9. The method of claim 6 wherein the photoresist layer is formed of a positive photoresist material.

10. The method of claim 6 wherein the photoresist layer is formed of a negative photoresist material.

11. The method of claim 6 wherein the exposure conditions include exposure energy.

12. The method of claim 6 wherein the exposure conditions include depth of focus.

13. The method of claim 6 wherein the exposure conditions include illumination.

14. A method for forming a patterned layer comprising:
providing a substrate having formed thereover a target layer having formed thereover a photoresist layer;
exposing within a single die region within the photoresist layer a minimum of two non-overlapping die sub-patterns while employing a minimum of two masks, to form an exposed photoresist layer;
developing the exposed photoresist layer to form a patterned photoresist layer; and
processing the target layer to form a processed target layer while employing the patterned photoresist layer as a mask layer.

15. The method of claim 1 wherein the substrate is a semiconductor substrate.

16. The method of claim 1 wherein the substrate is a ceramic substrate.

17. The method of claim 1 wherein the blanket photoresist layer is formed of a positive photoresist material.

18. The method of claim 1 wherein the blanket photoresist layer is formed of a negative photoresist material.

19. The method of claim 1 wherein the exposing of the photoresist layer employing two masks also employs at least two separate exposure conditions.

20. The method of claim 19 wherein the separate exposure conditions are selected from the group including exposure energy, depth of focus and illumination.
